(19) United States
(12) Patent Application Publication
(10) Pub. No.: US 2006/0189160 A1
(43) Pub. Date: Aug. 24, 2006

(54) Method for producing a pattern formation mold

(76) Inventors: Tadashi Hattori, Himeji-shi (JP); Yuichi Utsumi, Himeji-shi (JP); Nobuji Sakai, Inba-gun (JP); Kentaro Tada, Inba-gun (JP)

Correspondence Address: GOMEZ INTERNATIONAL PATENT OFFICE, LLC, 1501 N. RODNEY STREET, SUITE 101, WILMINGTON, DE, 19806, US

(21) Appl. No.: 10/526,384

(22) PCT Filed: Aug. 29, 2003
(86) PCT No.: PCT/JP03/11028

§ 371 Date: Mar. 27, 2006

(30) Foreign Application Priority Data
Aug. 30, 2002 (JP) 2002-252920

(51) Int. Cl. H01L 21/31; H01L 21/469

(52) U.S. Cl. 438/780

(57) ABSTRACT

The method for producing a pattern formation mold includes: a first step of applying to a substrate a radiation-sensitive negative-type resist composition containing an epoxy resin represented by formula (I): (wherein R¹ represents a moiety derived from an organic compound having k active hydrogen atoms (k represents an integer of 1 to 100); each of n₁, n₂, through nₖ represents 0 or an integer of 1 to 100; the sum of n₁, n₂, through nₖ falls within a range of 1 to 100; and each of “A” s, which may be identical to or different from each other, represents an oxycyclohexane skeleton represented by formula (II): (wherein X represents any of groups represented by formulas (III) to (V): and at least two groups represented by formula (III) are contained in one molecule of the epoxy resin)), along with a radiation-sensitive cationic polymerization initiator, and a solvent for dissolving the epoxy resin therein; a second step of drying the substrate coated with the radiation-sensitive negative-type resist composition, to thereby form a resist film; a third step of selectively exposing the formed resist film to an active energy beam according to a desired pattern; a fourth step of heating the exposed resist film so as to enhance a contrast of a pattern to be formed; a fifth step of developing the heated resist film, to thereby remove the unexposed area of the resist film through dissolution, thereby forming a patterned layer; and a sixth step of applying to the patterned layer a material other than that of the patterned layer such that spaces present in the patterned layer are filled, at least to some height, with the material, to thereby form a second layer, and removing the second layer, to thereby yield a pattern formation mold.

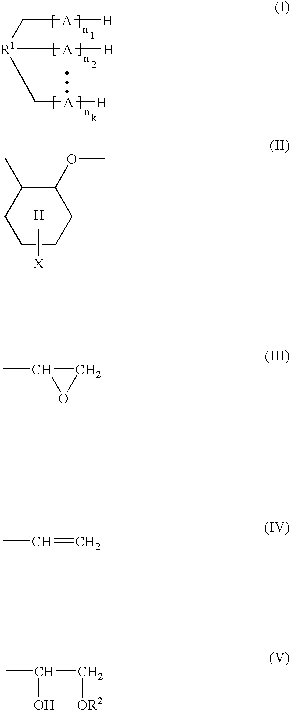

### TECHNICAL FIELD

The present invention relates to a method for producing a pattern formation mold. More particularly, the invention relates to a method for producing a pattern formation mold which is suitably employed as a technique that can be applied to, for example, a photolithography step included in the LIGA process and capable of readily producing a pattern formation mold for producing a pattern having a high aspect ratio (hereinafter referred to as a high-aspect pattern) with high precision.

### BACKGROUND ART

The LIGA process has been employed as a technique for producing microparts. The LIGA process is a technique which includes a lithography step for forming a resist pattern matching the pattern of a target part, an electroforming step for forming a metal pattern, and a resin molding step employing the metal pattern, to thereby produce microparts on a large scale. The LIGA process is explained in Chapter 1 of the book entitled “LIGA Process” (published by The Nikkan Kogyo Shimbun, Ltd.), and techniques of process elements thereof are disclosed in Chapter 2 of the same book. In the lithography step of the LIGA process, a very thick resist film having a thickness of generally more than 50 μm, in some cases more than 100 μm, is processed to form a high-aspect pattern. Thus, the type of the active energy beam employed in the lithography step is limited, and an X-ray based on synchrotron radiation or obtained by other means is generally employed.

The X-ray derived from synchrotron radiation penetrates a resist material with high transmissivity and travels in a straight line. These features contribute to formation of a high-aspect pattern, and thus the synchrotron-radiation X-ray has been used in the art. Generally, PMMA (polymethyl methacrylate) is used as a resist material. In addition, Japanese Patent Publication (kokoku) No. 7-78628 (relating to a printed circuit board) discloses that a resist material, SU-8 (trade name, negative-type resist), can be used in the LIGA process. The material SU-8 is a composition to be cured through photo-cationic polymerization and contains an epoxy resin and a radiation-sensitive cationic polymerization initiator. As compared with an acrylate-based composition to be cured through radical photopolymerization, SU-8 is known to undergo less shrinkage during curing reaction. Thus, SU-8 is suited for the LIGA process for processing a very thick film.

However, as disclosed, for example, by J. Mohr, W. Ehrfeld, and D. Meunchmeryer in J. Vac. Sci. Technol., B6, 2264 (1988), the PMMA coating method includes considerably cumbersome steps, and the precision in film thickness is poor, since methyl methacrylate (monomer) is polymerized on a substrate. In addition, although a very high-intensity X-ray based on synchrotron radiation is used to process a thick PMMA film, the process cannot be employed in practice, in view of a considerably long process time. Furthermore, PMMA has a problem of insensitivity to a generally used light source; i.e., a high-pressure mercury lamp. Synchrotron radiation advantageously attains considerably high pattern precision, but is not an advantageous light source, in view that it requires a large-scale apparatus.

SU-8, having considerably high sensitivity to a high-pressure mercury lamp and excellent patterning characteristics, also has a problem in that it exhibits intense absorption in a deep UV region (wavelength: ≦300 nm) attributed to an aromatic ring included in the skeleton of novolak epoxy resin used in the material, imposing a limitation on the wavelength of exposure light. Studies conducted in recent years have confirmed that, in semiconductor microprocessing, shifting the wavelength of exposure light to a shorter wavelength in the UV region effectively enhances pattern precision. Therefore, another demerit of SU-8 is that it cannot be used in the deep UV region. Furthermore, a cationic initiator must be selected in accordance with light absorption (transparency) of the resin. Since most commercial cationic initiators have absorption bands similar in wavelength range to those of novolak epoxy resin, the initiator must be selected from a limited range of commercial cationic initiators, and this is also problematic.

Some commercially available monomer products for producing an aliphatic epoxy resin have no aromatic group. Examples include glycidyl (meth)acrylate, CYCLOMER A200 and CYCLOMER M100 ((meth)acrylate having an aliphatic epoxy group, products of Daicel Chemical Industries, Ltd.), and Celloxide 2000 (1-vinyl-3,4-epoxycyclohexane, product of Daicel Chemical Industries, Ltd.). These monomers are polymerized through radical polymerization or a similar method, to thereby synthesize epoxy resins.

However, (meth)acrylates such as glycidyl (meth)acrylate, CYCLOMER A200, and CYCLOMER M100 have a (meth)acrylate ester backbone and are known to have relatively high sensitivity to high-energy active beams such as electron beams, deep UV rays, and X-rays. When the (meth)acrylates are irradiated with any such active beams, a side reaction other than the target epoxy-group-polymerization occurs in the backbone, greatly varying and affecting physical properties (e.g., patterning characteristics, sensitivity to exposure, characteristics of cured products) of the produced resins. Thus, such a high sensitivity is not preferred. Celloxide 2000 has no (meth)acrylate backbone, but raises concerns over its toxicity. Therefore, it must be used under strict control, which is also problematic.

### DISCLOSURE OF THE INVENTION

In view of the foregoing, an object of the present invention is to provide a method for producing a pattern formation mold formed of metal, resin, etc. from a high-aspect pattern having high pattern precision, the high-aspect pattern being produced through a method in which a resist composition can be applied to a substrate in a simple manner so as to accurately control film thickness (e.g., spin coating); the target level of pattern precision and the light source for exposure can be selected from wide ranges; and high productivity is attained by virtue of requirement of a short exposure time.

The present inventors have carried out extensive studies in order to solve the aforementioned problems, and have found that, when a specific epoxy resin having no (meth)acrylate skeleton is employed in pattern formation, particularly when employed in combination with a specific initiator, there can be produced a pattern formation mold formed of metal, resin, etc. from a high-aspect pattern having high pattern precision, the high-aspect pattern being produced through a method in which a resist composition can be applied to a substrate in a simple manner so as to accurately control film thickness (e.g., spin coating); the target level of pattern precision and the light source for exposure can be selected from wide ranges; and high productivity is attained by virtue of requirement of a short exposure time. The present invention has been accomplished on the basis of this finding.

Accordingly, a first mode of the present invention is drawn to a method for producing a pattern formation mold, characterized in that the method comprises: a first step of applying to a substrate a radiation-sensitive negative-type resist composition containing an epoxy resin represented by formula (1): 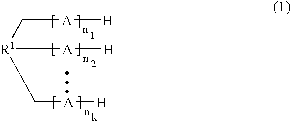
(wherein R¹ represents a moiety derived from an organic compound having k active hydrogen atoms (k represents an integer of 1 to 100); each of n₁, n₂, through nₖ represents 0 or an integer of 1 to 100; the sum of n₁, n₂, through nₖ falls within a range of 1 to 100; and each of “A”s, which may be identical to or different from each other, represents an oxycyclohexane skeleton represented by formula (2): 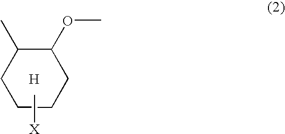
(wherein X represents any of groups represented by formulas (3) to (5): 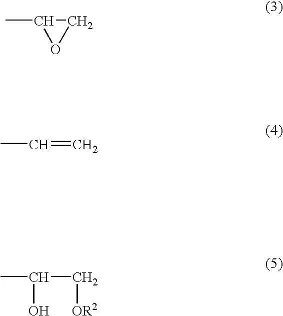
(wherein R² represents a hydrogen atom, an alkyl group, or an acyl group, herein, an alkyl group and an acyl group preferably have 1 to 20 carbon atoms, respectively), and at least two groups represented by formula (3) are contained in one molecule of the epoxy resin)), along with a radiation-sensitive cationic polymerization initiator, and a solvent for dissolving the epoxy resin therein; a second step of drying the substrate coated with the radiation-sensitive negative-type resist composition, to thereby form a resist film; a third step of selectively exposing the formed resist film to an active energy beam according to a desired pattern; a fourth step of heating the exposed resist film so as to enhance a contrast of a pattern to be formed; a fifth step of developing the heated resist film, to thereby remove the unexposed area of the resist film through dissolution, thereby forming a patterned layer; and a sixth step of applying to the patterned layer a material other than that of the patterned layer such that spaces present in the patterned layer are filled, at least to some height, with the material, to thereby form a second layer, and removing the second layer, to thereby yield a pattern formation mold.

A second mode of the present invention is directed to a method for producing a pattern formation mold mentioned in relation to the first mode, wherein the second layer is formed through metal plating.

A third mode of the present invention is directed to a method for producing a pattern formation mold mentioned in relation to the first mode, wherein the second layer is formed by casting a photo-curable or heat-curable resin and curing the resin by light or heat.

A fourth mode of the present invention is directed to a method for producing a pattern formation mold mentioned in relation to any one of the first to third modes, wherein the resist film formed by drying the radiation-sensitive negative-type resist composition has a softening point falling within a range of 30 to 120° C.

A fifth mode of the present invention is directed to a method for producing a pattern formation mold mentioned in relation to any one of the first to fourth modes, wherein the epoxy resin has a softening point of 30° C. or higher.

A sixth mode of the present invention is directed to a method for producing a pattern formation mold mentioned in relation to any one of the first to fifth modes, wherein the radiation-sensitive cationic polymerization initiator comprises one or more sulfonium salts.

A seventh mode of the present invention is directed to a method for producing a pattern formation mold mentioned in relation to any one of the first to sixth modes, wherein the radiation-sensitive cationic polymerization initiator has one or more anion moieties, at least one species of the anion moieties being SbF₆⁻.

An eighth mode of the present invention is directed to a method for producing a pattern formation mold mentioned in relation to any one of the first to seventh modes, wherein the radiation-sensitive cationic polymerization initiator has one or more anion moieties, at least one species of the anion moieties being a borate represented by formula (6): 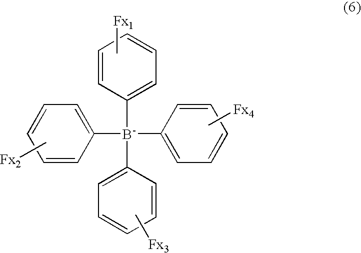
(wherein each of x₁ to x₄ represents an integer of 0 to 5, and the sum x₁+x₂+x₃+x₄ is 1 or more).

A ninth mode of the present invention is directed to a method for producing a pattern formation mold mentioned in relation to any one of the first to eighth modes, wherein the active energy beam is an X-ray having a wavelength of 0.1 to 5 nm.

A tenth mode of the present invention is directed to a method for producing a pattern formation mold mentioned in relation to any one of the first to ninth modes, wherein the resist film has a thickness of at least 50 μm.

### BRIEF DESCRIPTION OF THE DRAWINGS

FIGS. 1A to 1C show a procedure for producing a pattern formation mold according to one embodiment of the present invention.

FIGS. 2A to 2C show a procedure for producing a pattern formation mold according to another embodiment of the present invention.

### BEST MODES FOR CARRYING OUT THE INVENTION

According to the present invention, a pattern formation mold is produced from a high-aspect pattern which can be formed at high productivity in a simple manner by use of a variety of light sources. The pattern formation mold produced through the production method of the present invention can be employed as a “mold” for forming other parts having a pattern similar to that of the resist pattern. The pattern formation mold produced through the production method of the present invention itself can also be used as a part, such as a micromachine or a microchip.

One characteristic feature of the present invention resides in employment of a particular epoxy resin represented by formula (1) selected from among a number of conventionally employed curable resin compositions. Through such a selection, there can be obtained a resist pattern having a high aspect ratio at high productivity in a simple manner by use of any of a variety of light sources. Thus, a pattern formation mold can be conveniently produced by use of such a resist pattern. Meanwhile, Japanese Patent Application Laid-Open (kokai) No. 60-166675 discloses the above epoxy resin, and Japanese Patent Application Laid-Open (kokai) No. 61-283614 discloses a curable resin composition predominantly containing the epoxy resin and a photo-initiator. Notably, the latter document discloses that the curable resin composition has been developed only as a UV-curable resin composition, and provides no description about pattern formation by use of the resin composition. Needless to say, the document provides no description indicating the method of the present invention; i.e., a method for producing a pattern formation mold formed of metal or a similar material, particularly a method for producing a pattern formation mold including formation of a thick-film pattern performed in the LIGA process. Therefore, those skilled in the art would not easily conceive the effect of the present invention that a pattern formation mold can be beneficially produced by use of a resist pattern having a high aspect ratio which can be formed at high productivity in a simple manner by use of any of a variety of light sources.

The method for producing a pattern formation mold of the present invention includes: a first step of applying to a substrate a radiation-sensitive negative-type resist composition containing an epoxy resin represented by formula (1), a radiation-sensitive cationic polymerization initiator, and a solvent for dissolving the epoxy resin therein; a second step of drying the substrate coated with the radiation-sensitive negative-type resist composition, to thereby form a resist film; a third step of selectively exposing the formed resist film to an active energy beam according to a desired pattern; a fourth step of heating the exposed resist film so as to enhance a contrast of a pattern to be formed; a fifth step of developing the heated resist film, to thereby remove the unexposed area of the resist film, thereby forming a patterned layer; and a sixth step of applying to the patterned layer with a material other than that of the patterned layer such that spaces present in the patterned layer are filled, at least to some height, with the material, to thereby form a second layer, and removing the second layer, to thereby yield a pattern formation mold.

The radiation-sensitive negative-type resist composition which is applied to a substrate in the first step contains an epoxy resin represented by formula (1), a radiation-sensitive cationic polymerization initiator, and a solvent for dissolving the epoxy resin therein. Such a radiation-sensitive negative-type resist composition can be applied to a substrate in a manner which is simple and attains high precision and control in film thickness (e.g., spin coating). No particular limitation is imposed on the softening point of the resist film formed by drying the radiation-sensitive negative-type resist composition, and the softening point preferably falls within a range of 30 to 120° C., more preferably a range of 35 to 100° C., most preferably a range of 40 to 80° C. The “softening point” is determined through measurement of the resist film formed through a predetermined drying step. The term “resist film formed through a predetermined drying step” refers to a resist film which is obtained by drying a radiation-sensitive negative-type resist composition applied to a substrate so as to control the amount of the solvent remaining in the resist film to 10 wt. % or less. When the resist film formed through drying is heated, the form of the film gradually changes from solid of high viscosity to fluid of low viscosity. The temperature at which a specific viscosity is obtained during the softening step is evaluated as the softening point of the resist film formed through drying. Specifically, the temperature is determined in accordance with the method of JIS K 7234.

The thus-determined softening point of the resist film formed by drying the radiation-sensitive negative-type resist composition varies in accordance with mainly the type and content of the epoxy resin or the radiation-sensitive cationic polymerization initiator, as well as with the type, amount, and other parameters of the solvent remaining during drying or other additives. In other words, when these parameters are modified, the softening point can be controlled. As described above, the softening point of the resist film which is formed by drying a resist composition so as to control the amount of the solvent remaining in the resist film to 10 wt. % or less preferably falls within a range of 30 to 120° C. However, no particular limitation is imposed on the dryness of the radiation-sensitive negative-type resist composition. Thus, when a resist composition having a softening point falling within the aforementioned range is used, the amount of solvent remaining in the film after the drying step may exceed 10 wt. % in the second step.

The aforementioned negative-type resist composition can be processed in the form of thick film having a thickness in excess of 50 μm. When such a thick film is processed, removal of a volatile component during the drying step causes reduction in volume of the film, thereby generating stress. In contrast with the case of a conventional thin resist film processing, the stress must be removed. The reason for removing the stress is that, when the resist film has a great thickness, the effect of the stress considerably increases, and defects such as creases, cracks, and foam tend to be generated in the resist film. As described above, when the negative-type resist composition exhibits a softening point of the resist film formed by drying the composition falling within the aforementioned temperature range, the stress generated in the film is relaxed by softening of the resist film during drying, to thereby prevent creases or other defects of the resist film. In addition, generation of folds at room temperature is prevented.

The polyether-type epoxy resin represented by formula (1) is produced by, for example, reacting 4-vinylcyclohexene-1-oxide with an organic compound having active hydrogen in the presence of a catalyst, to thereby yield a polyether compound and by partially or completely epoxidizing vinyl groups of the polyether compound by use of an oxidizing agent such as a peracid (e.g., peracetic acid) or a hydroperoxide. In this case, a small amount of acyl groups and similar groups may be introduced to the epoxy resin. Examples of organic compounds having active hydrogen include alcohols (e.g., linear or branched aliphatic alcohols, preferably polyhydric alcohols such as trimethylolpropane), phenols, carboxylic acids, amines, and thiols. Herein, organic compounds having active hydrogen preferably have a molecular weight of ten thousand or less. Notably, a moiety derived by removing active hydrogen from any of organic compounds having active hydrogen serves as R¹ in formula (1). Examples also includes commercially available products (e.g., EHPE-3150 (epoxy equivalent: 170 to 190, softening point: 70 to 90° C., product of Daicel Chemical Industries, Ltd.)).

No particular limitation is imposed on the softening point of the epoxy resin represented by formula (1). However, the softening point is preferably 30° C. or higher, more preferably 40 to 140° C., since excessively low temperatures tend to generate folds in the dried resist film.

No particular limitation is imposed on the radiation-sensitive cationic polymerization initiator contained in the radiation-sensitive negative-type resist composition, and a known initiator can be used, so long as the initiator generates an acid upon irradiation with an active energy beam. Examples of the initiator include sulfonium salts, iodonium salts, phosphonium salts, and pyridinium salts.

Examples of the sulfonium salts include triphenylsulfonium hexafluorophosphate, triphenylsulfonium hexafluoroantimonate, bis(4-(diphenylsulfonio)-phenyl)sulfide bis(hexafluorophosphate), bis(4-(diphenylsulfonio)-phenyl)sulfide bis(hexafluoroantimonate), 4-di(p-toluyl)sulfonio-4′-tert-butylphenylcarbonyl-diphenylsulfide hexafluoroantimonate, 7-di(p-toluyl)sulfonio-2-isopropylthioxanthone hexafluorophosphate, 7-di(p-toluyl)sulfonio-2-isopropylthioxanthone hexafluoroantimonate, and aromatic sulfonium salts disclosed in Japanese Patent. Application Laid-Open (kokai) Nos. 7-61964 and 8-165290, U.S. Pat. Nos. 4,231,951 and 4,256,828, etc.

Examples of the iodonium salts include diphenyliodonium hexafluorophosphate, diphenyliodonium hexafluoroantimonate, bis(dodecylphenyl)iodonium tetrakis(pentafluorophenyl)borate, and aromatic iodonium salts disclosed in Japanese Patent Application Laid-Open (kokai) No. 6-184170, U.S. Pat. No. 4,256,828, etc.

Examples of the phosphonium salts include tetrafluorophosphonium hexafluorophosphate, tetrafluorophosphonium hexafluoroantimonate, and aromatic phosphonium salts disclosed in Japanese Patent Application Laid-Open (kokai) No. 6-157624, etc.

Examples of the pyridinium salts include pyridinium salts disclosed in Japanese Patent No. 2519480, Japanese Patent Application Laid-Open (kokai) No. 5-222112, etc.

The aforementioned negative-type resist composition can be processed in the form of thick film having a thickness in excess of 50 μm. When such a thick film is processed, the drying time required in the step of drying the applied resist liquid and the development time in the developing step increase, which differs from the case of a conventional thin resist film processing. Thus, when a thick film of the aforementioned negative-type resist composition is formed, the composition is required to possess high thermal stability and a high contrast between the exposed area and the unexposed area. Therefore, the radiation-sensitive cationic polymerization initiator preferably includes one or more sulfonium salts, because thermal stability of the negative-type resist composition increases when the composition contains, among the aforementioned radiation-sensitive cationic polymerization initiators, a sulfonium salt.

At least one of the anion moieties of the radiation-sensitive cationic polymerization initiator is preferably SbF₆⁻ or a borate represented by formula (6) 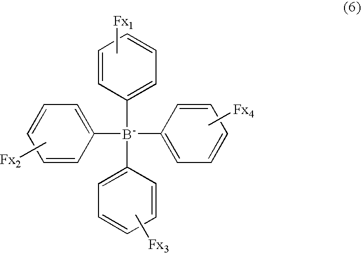
(wherein each of x₁ to x₄ represents an integer of 0 to 5, and the sum x₁+x₂+x₃+x₄ is 1 or more). When these anion moieties are included, the negative-type resist composition beneficially exhibits a high contrast. Examples of more preferred borates include tetrakis(pentafluorophenyl)borate.

The sulfonium salts and iodonium salts may be products that are readily available on the market. Examples of such radiation-sensitive cationic polymerization initiators include sulfonium salts such as UVI-6990 and UVI-6974 (products of Union Carbide) and Adeka Optomer SP-170 and Adeka Optomer SP-172 (products of Asahi Denka Kogyo K.K.) and iodonium salts such as PI 2074 (product of Rhodia).

No particular limitation is imposed on the amount of the radiation-sensitive cationic polymerization initiator added to the resist composition. However, the amount is preferably 0.1 to 15 parts by weight, more preferably 1 to 12 parts by weight, based on 100 parts by weight of the epoxy resin.

No particular limitation is imposed on the solvent for dissolving therein the epoxy resin contained in the radiation-sensitive negative-type resist composition, and any solvent can be used so long as it can dissolve the epoxy resin. Examples of the solvent include propylene glycol monoalkyl ether acetates such as propylene glycol monomethyl ether acetate and propylene glycol monoethyl ether acetate; alkyl lactate esters such as methyl lactate and ethyl lactate; propylene glycol monoalkyl ethers such as propylene glycol monomethyl ether and propylene glycol monoethyl ether; ethylene glycol monoalkyl ethers such as ethylene glycol monomethyl ether and ethylene glycol monoethyl ether; ethylene glycol monoalkyl ether acetates such as ethylene glycol monomethyl ether acetate and ethylene glycol monoethyl ether acetate; 2-heptanone; γ-butyrolactone; alkyl alkoxypropionates such as methyl methoxypropionate and ethyl ethoxypropionate; alkyl pyruvate esters such as methyl pyruvate and ethyl pyruvate; ketones such as methyl ethyl ketone, cyclopentanone, and cyclohexanone; N-methylpyrrolidone; N,N-dimethylacetamide; dimethyl sulfoxide; propylene carbonate; and diacetone alcohol. These solvents may be used singly or in combination of two or more species. Among these solvents, γ-butyrolactone is particularly preferred.

The radiation-sensitive negative-type resist composition containing the aforementioned components preferably has a solid content of 10 to 90 wt. % based on the solvent for dissolving the epoxy resin, more preferably 40 to 85 wt. %, more preferably 60 to 80 wt. %. When the solid content is excessively low, application of the composition to form a thick film is difficult, whereas when the solid content is excessively high, application of the composition is difficult, in view of greatly increased viscosity.

Notably, the aforementioned radiation-sensitive negative-type resist composition may contain, in accordance with needs, a variety of additives such as a surfactant, an acid-diffusion-suppressor, a pigment, a dye, a sensitizer, and a plasticizer.

No particular limitation is imposed on the material and surface of the substrate to which the negative-type resist composition is applied. For example, the substrate may be formed of silicon, glass, metal, ceramics, organic polymer, etc. These substrates may be subjected to pre-treatment in order to enhance adhesion with the resist composition or other properties. Specifically, silane treatment is performed so as to enhance adhesion with the resist composition. In the case in which a metal-made pattern formation mold is produced, the surface of the substrate is readily plated so as to impart electrical conductivity to the surface.

No particular limitation is imposed on the method for applying the radiation-sensitive negative-type resist composition to a substrate, and coating methods such as screen printing, curtain coating, blade coating, spin coating, spray coating, dip coating, and slit coating can be employed.

The substrate to which the radiation-sensitive negative-type resist composition has been applied in the first step is dried in the second step, to thereby form a resist film. No particular limitation is imposed on the method for drying, and the drying step is preferably performed under conditions (temperature and time) such that the solvent contained in the negative-type resist composition is vaporized and fold-free resist film is formed, and such that the epoxy resin, radiation-sensitive cationic polymerization initiator, and optionally added additive do not cause thermal reaction which adversely affects pattern formation. Thus, preferred drying conditions include, for example, 40 to 120° C., and 5 minutes to 24 hours. No particular limitation is imposed on the thickness of the resist film. Even when the resist film has a thickness, for example, as great as 50 μm or more, the film can be processed with precision in the subsequent steps. A thickness of 50 μm to 2 mm is particularly preferred.

In the third step, the resist film which has been formed in the second step is selectively exposed to an active energy beam according to a desired pattern. No particular limitation is imposed on the active energy beam for exposure, and examples include UV rays, excimer laser beams, electron beams, and X-rays. Use of an X-ray having a wavelength of 0.1 to 5 nm is particularly preferable, since high pattern precision is attained. Notably, since the production method of the present invention employs the aforementioned radiation-sensitive negative-type resist composition, even when the resist film has a thickness, for example, as great as 50 μm or more, only a short exposure time is required and the type of the active energy beam can be selected in accordance with the desired pattern precision. Specifically, high productivity is attained, since highly useful UV-rays (light source: high-pressure mercury lamp) can be used.

In the fourth step, the resist film which has been exposed to the active energy beam is heated to enhance contrast. If this fourth step is omitted, reaction to form epoxy resin is not fully complete, thereby failing to form a high precision pattern. In the fourth step, the heat treatment must be performed within a time and temperature where thermal reaction of the unexposed resist area to be insoluble in a developer is prevented. The temperature is preferably 70 to 110° C., more preferably 80 to 100° C., and the time is preferably 5 minutes to 10 hours. When the temperature is lower than the above range or the time is shorter than the above range, the contrast is poor, whereas when the temperature is excessively high or the time is excessively long, a problem such as formation of the unexposed area insoluble in a developer arises.

In the fifth step, the resist film which has been heat-treated in the fourth step is developed to remove the unexposed area of the resist through dissolution, thereby forming a patterned layer. Notably, the resist film formed in the present invention has a large thickness and high strength and resolution, whereby a high-aspect pattern, layer can be formed. For example, a pattern of an aspect ratio of 10 or higher can be formed.

No particular limitation is imposed on the species of developer, and any solvent can be used so long as the solvent is capable of removing the unexposed portion of the negative-type resist through dissolution. Examples of the solvent serving as a developer include propylene glycol monoalkyl ether acetates such as propylene glycol monomethyl ether acetate and propylene glycol monoethyl ether acetate; alkyl lactate esters such as methyl lactate and ethyl lactate; propylene glycol monoalkyl ethers such as propylene glycol monomethyl ether and propylene glycol monoethyl ether; ethylene glycol monoalkyl ethers such as ethylene glycol monomethyl ether and ethylene glycol monoethyl ether; ethylene glycol monoalkyl ether acetates such as ethylene glycol monomethyl ether acetate and ethylene glycol monoethyl ether acetate; 2-heptanone; γ-butyrolactone; alkyl alkoxypropionates such as methyl methoxypropionate and ethyl ethoxypropionate; alkyl pyruvate esters such as methyl pyruvate and ethyl pyruvate; ketones such as methyl ethyl ketone, cyclopentanone, and cyclohexanone; N-methylpyrrolidone; N,N-dimethylacetamide; dimethyl sulfoxide; propylene carbonate; and diacetone alcohol. Of these, γ-butyrolactone, propylene glycol monomethyl ether acetate, etc. are particularly preferred.

The development can be performed any of a variety of methods, such as the spray method, the paddle method, and immersion. Among these immersion is preferred, because breakage of patterns such as peeling is prevented. In addition, ultrasonication may be performed in accordance with needs.

In the fifth step, in accordance with needs a rinse step is preferably performed after completion of the development. No particular limitation is imposed on the mode of the rinse step, the rinse liquid, and the rinsing method, and known rinse liquids and methods can be employed.

In addition, after completion of the development and the rinse step, the resist pattern may be stabilized through heating under known conditions.

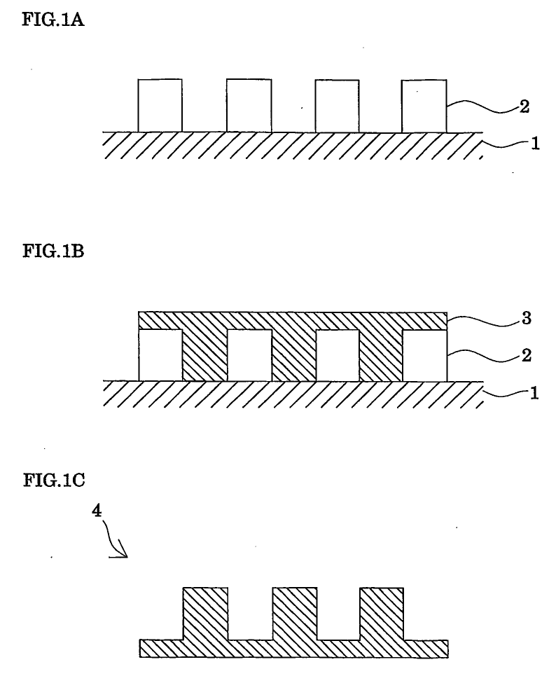

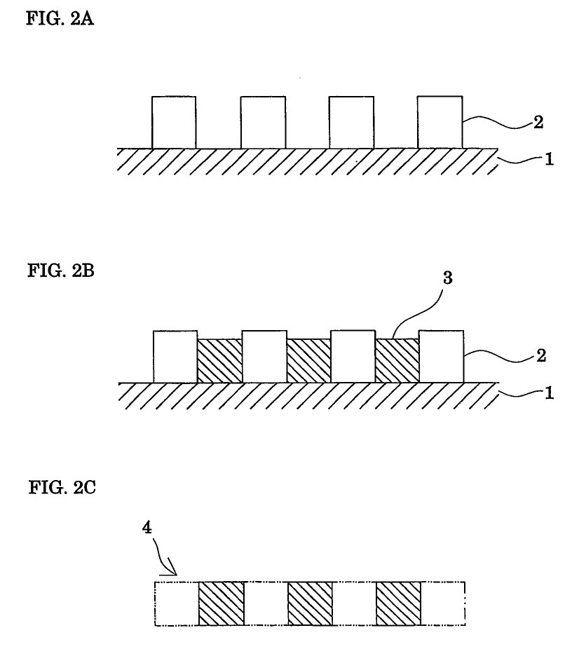

In the sixth step, a material other than that of the patterned layer which has been formed in the fifth step is applied to the patterned layer such that spaces present in the patterned layer are filled, at least to some height, with the material, to thereby form a second layer, and the second layer is removed, to thereby yield a pattern formation mold. Specifically, as shown in FIGS. 1 and 2, a second layer 3 formed of a material other than that of a patterned layer 2 (FIGS. 1A and 2A) formed on a substrate 1 is provided such that spaces present in the patterned layer 2 are filled, at least to some height, with the material, to thereby produce a composite structure of the patterned layer 2 and the second layer 3 (FIGS. 1B and 2B). Notably, the second layer 3 may be provided exclusively in the space present in the patterned layer 2 or may be provided such that the second layer completely covers the surface of the patterned layer 2. By removing the second layer 3 from the composite structure of the patterned layer 2 and the second layer 3, a pattern formation mold 4 to which the resist pattern of the patterned layer 2 is transferred is produced (FIGS. 1C and 2C). The pattern formation mold 4 can be employed as a “mold” for forming other parts, or the mold itself can also be used as a part.

As described above, according to the present invention, a high-aspect resist pattern layer can be formed. Thus, a pattern formation mold to which the high-aspect pattern is transferred can be produced. For example, the aspect ratio can be enhanced to 10 or higher.

No particular limitation is imposed on the material for forming the second layer 3. When a metal is used as the material, a metal-made pattern formation mold can be produced through a step; e.g., a plating step.

Although no particular limitation is imposed on the method for performing the plating step, electroplating is preferred. Plating of copper, nickel, silver, gold, solder, copper/nickel multilayer, a complex system thereof, etc. can be performed through any known conventional method. Such methods are disclosed in, for example, Comprehensive Bibliography of Surface Treatment Techniques (published by Technical Material Center, 1987 Dec. 21, 1st edition, p. 281-422).

No particular limitation is imposed on the method for separating the second layer 3 formed through the plating step from the composite structure of the patterned layer 2 and the second layer 3, and known wet methods and dry methods can be employed. In one wet method, immersion in an organic solvent such as N-methylpyrrolidone or in an organic alkaline solution agent such as ethanolamine solution is employed. In one dry method, dry etching (e.g., reactive ion etching) or ashing is employed.

The material for forming the second layer 3 may be a resin. In this case, a resin-made pattern formation mold can be produced by, for example, casting a photocurable or thermosetting (heatcurable) resin to form the second layer 3, and photo-curing or thermally curing the cast resin.

Also, no particular limitation is imposed on the method for separating the second layer 3 formed of a photocurable or thermosetting resin from the composite structure of the patterned layer 2 and the second layer 3. For example, the second layer can be physically separated. When the second layer 3 has sufficient resistance to the aforementioned wet method and dry method, both methods can also be employed. No particular limitation is imposed on the species of the photocurable or thermosetting resin. When a photocurable or thermosetting PDMS (polydimethylsiloxane) is employed, pattern transfer can be performed by readily curing PDMS through light or heat. The thus-formed second layer can be readily removed from the resist pattern through a physical method. Thus, the PDMS is particularly preferred.

### EXAMPLES

The present invention will next be described in detail by way of examples, which should not be construed as limiting the invention thereto.

1. Preparation of radiation-sensitive negative-type resist composition for pattern formation

### Examples 1 to 4

The resist materials were mixed in the proportions shown in Table 1, and the resultant mixture was uniformly kneaded by means of a three-roll mill, to thereby prepare the respective radiation-sensitive negative-type resist compositions for pattern formation. The structures and product names of the epoxy resins and cationic polymerization initiators are shown below.

TABLE 1

| | Epoxy resin | Cationic polymerization initiator | Solvent (γ-butyrolactone) |
|---|---|---|---|
| Example 1 | Resin-1 | PI-1 | 22.0 g |
| | 70.0 g | 8.0 g | |
| Example 2 | Resin-1 | PI-2 | 22.0 g |
| | 70.0 g | 8.0 g | |
| Example 3 | Resin-1 | PI-3 + | 26.0 g |
| | 70.0 g | diethylthioxanthone | |
| | | 4.0 g + 0.5 g | |
| Example 4 | Resin-1 | PI-4 | 26.0 g |
| | 70.0 g | 4.0 g | |
| Comparative Example 1 | Resin-2 | PI-1 | 25.0 g |
| | 70.0 g | 8.0 g | |

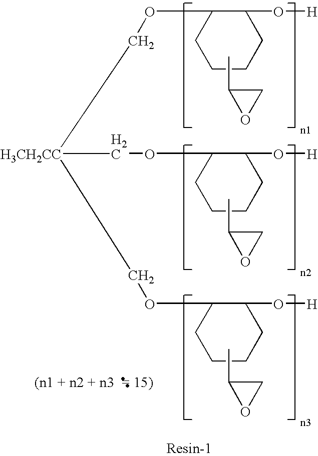

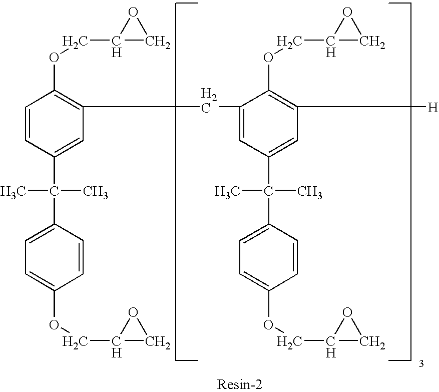

Resin-1: EHPE-3150 (epoxy resin, product of Daicel Chemical
Industries, Ltd.)
Resin-2: EPON SU-8 (epoxy resin, product of Shell Chemical)

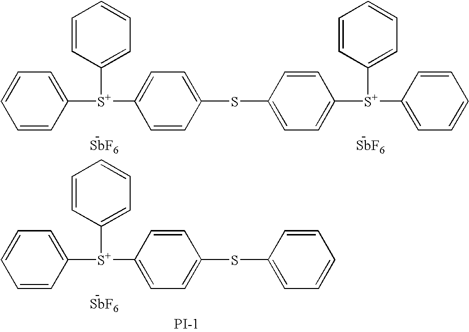

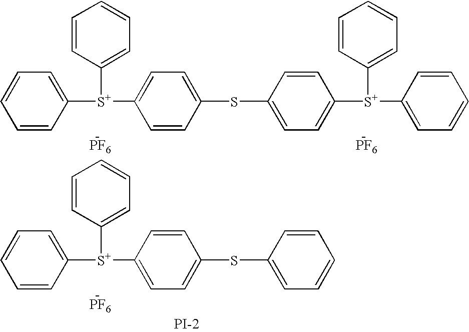

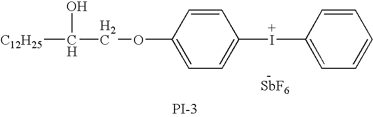

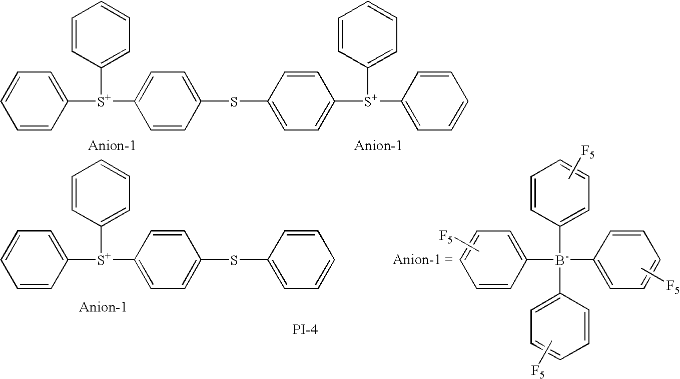

PI-1: UVI-6974 (cationic polymerization initiator, product of
Union Carbide, a mixture predominantly containing the above
PI-1, effective ingredient content: 50 wt. %)
PI-2: UVI-6990 (cationic polymerization initiator, product of
Union Carbide, a mixture predominantly containing the above
PI-2, effective ingredient content: 50 wt. %)
PI-3: SarCat CD-1012 (cationic polymerization initiator,
product of Sartomer Co.)
PI-4: A mixture predominantly containing PI-4.

### Comparative Example 1

In a manner similar to that of Examples 1 to 4, a radiation-sensitive negative-type resist composition of Comparative Example 1 for pattern formation having a composition shown in Table 1 was prepared.

2. Evaluation of Patterning Characteristics

(1) Production of Resist Film

### Examples 1a to 4a

Each of the radiation-sensitive negative-type resist compositions for pattern formation of Examples 1 to 4 was applied by means of a spin-coater to a silicon substrate which had been surface-coated with copper through sputtering. Subsequently, the substrate was heated on a hot plate at 90° C. for 30 minutes so as to dry the resist composition, to thereby form a resist film having a thickness of 100 μm.

### Comparative Example 1a

The procedure of Examples 1a to 4a was repeated, except that the radiation-sensitive negative-type resist composition of Comparative Example 1 was used instead of the radiation-sensitive negative-type resist compositions of Examples 1 to 4, to thereby form a resist film having a thickness of 100 μm.

### Comparative Example 2a

PMMA Syrup [product of Rohm, a mixture of PMMA (polymethyl methacrylate), a thermal polymerization initiator, and an MMA (methyl methacrylate) solution serving as a cross-linking agent] was cast into a space formed by glass slides on a silicon substrate. The cast mixture was covered with a glass plate disposed on the glass slides and polymerized at 110° C. for one hour for curing. The cured product was cooled at 15° C./hour, to thereby form a PMMA resist film having a thickness of 100 μm.

### Test Example 1

The thickness of each of the resist films produced in Examples 1a to 4a and Comparative Examples 1a and 2a was determined at three arbitrary points on the substrate, whereby uniformity of the film (coatability) was evaluated. Specifically, the case in which the difference between the maximum thickness and the minimum thickness was less than 5 μm was assigned a rating “AA”. Similarly, the case in which the difference was 5 to 10 μm was assigned a rating “BB”, and the case in which the difference was in excess of 10 μm was assigned a rating “CC”. Table 2 shows the results.

(2) Resist Pattern Formation

### Examples 1b to 4b

Each of the resist films produced in Examples 1a to 4a was irradiated with light. When a high-pressure mercury lamp or an KrF excimer laser was used as the light source, a quartz UV mask was used, whereas when an X-ray (wavelength: 0.2 to 1 nm) based on synchrotron radiation was used, a diamond membrane on which a gold light-absorbing pattern was formed was used as an X-ray mask. Subsequently, the substrate was heated on a hot-plate at 90° C. for 10 minutes, followed by immersion of the irradiated resist film in propylene glycol monomethyl ether acetate for 30 minutes for developing, to thereby form a resist pattern. The irradiation dose at each test is shown in Table 2.

### Comparative Example 1b

The procedure of Examples 1b to 4b was repeated, except that the resist film produced in Comparative Example 1a was used instead of the resist films produced in Examples 1a to 4a, to thereby form a resist pattern.

### Comparative Example 2b

The PMMA resist film of Comparative Example 2a was irradiated through a mask similar to that employed in Examples 1b to 4b. The thus-irradiated resist film was immersed in a mixture containing ethanol, oxazine, aminoethanol, and water for 12 hours with ultrasonication for developing, to thereby form a resist pattern.

### Test Example 2

Each of the resist patterns produced in Examples 1b to 4b and Comparative Examples 1b and 2b was observed under an optical microscope, to thereby evaluate the resist composition in terms of its sensitivity. Specifically, the case in which no curved or deformed portion of the pattern formed by swelling was observed was assigned a rating “AA”. Similarly, the case in which the top of the pattern had creases but no curved portion was observed was assigned a rating “BB”, and the case in which a curved portion was observed was assigned a rating “CC”.

The pattern was also evaluated in terms of the resolution of each resist composition. Specifically, the case in which the resist pattern was resolved at a mask width of 10 μm (aspect ratio: 10) was assigned a rating “AA”. Similarly, the case in which the resist pattern was resolved at a mask width of 20 μm (aspect ratio: 5) was assigned a rating “BB”, and the case in which the resist pattern was not resolved was assigned a rating “CC”. Table 2 shows the results.

TABLE 2

| | | Dose | Coata- | Sensi- | Reso- |
|---|---|---|---|---|---|
| | Light source | J/cm² | bility | tivity | lution |
| Examples | High-pressure mercury | 1 | AA | AA | AA |
| 1a and | lamp | | | | |
| 1b | KrF | 10 | AA | AA | AA |
| | Synchrotron radiation | 100 | AA | AA | AA |
| Examples | High-pressure mercury | 1 | AA | CC | CC |
| 2a and | lamp | 10 | AA | AA | BB |
| 2b | KrF | 100 | AA | BB | BB |
| | Synchrotron radiation | 1000 | AA | BB | BB |
| Examples | High-pressure mercury | 1 | AA | AA | BB |
| 3a and | lamp | | | | |
| 3b | KrF | 10 | AA | AA | BB |
| | Synchrotron radiation | 100 | AA | AA | BB |
| Examples | High-pressure mercury | 1 | AA | AA | AA |
| 4a and | lamp | | | | |
| 4b | KrF | 10 | AA | AA | AA |
| | Synchrotron radiation | 100 | AA | AA | AA |
| Compar- | High-pressure mercury | 1 | AA | AA | AA |
| ative | lamp | | | | |
| Examples | KrF | 10 | AA | Pattern not | |
| 1a and | | | | formed | |
| 1b | Synchrotron radiation | 100 | AA | AA | AA |
| Compar- | High-pressure mercury | 1 | CC | Pattern not | |
| ative | | | | formed | |
| Examples | lamp | 100 | CC | Pattern not | |
| 2a and | | | | formed | |
| 2b | KrF | 10 | CC | Pattern not | |
| | | | | formed | |
| | Synchrotron radiation | 100 | CC | Pattern not | |
| | | | | formed | |
| | | 10000 | CC | AA | AA |

The test results of Examples 1a and 4a indicate excellent coatability, and the test results of Examples 1b and 4b indicate excellent properties under all exposure conditions (light sources: high-pressure mercury lamp, KrF excimer laser beam, and X-ray based on synchrotron radiation).

The test results of Example 2a indicate excellent coatability. The test results of Example 2b indicate generally excellent properties, although curing sensitivity is slightly inferior to that obtained in Example 1b.

The test results of Example 3a indicate excellent coatability. The test results of Example 3b indicate generally excellent properties, although the development rate of unexposed portions was slow and the formed pattern was slightly affected.

The test results of Comparative Example 1a indicate excellent coatability. The test results of Comparative Example 1b indicate excellent properties under exposure conditions (light sources: high-pressure mercury lamp and X-ray based on synchrotron radiation). However, in Comparative Example 1b, a resist pattern was not formed through exposure to a KrF excimer laser beam.

In Comparative Example 2a, a resist film having a uniform thickness failed to be formed. The test results of Comparative Example 2b indicate that forming a resist pattern requires severe exposure conditions which are not practically employed (i.e., synchrotron radiation of 10,000 J/cm²).

3. Softening Point and Appearance of Resist Film Formed Through Drying

### Test Example 3

The softening point of the resist film of Example 1a was determined through the method specified by JIS K 7234, and the resist film was visually observed. As a result, the resist film was found to have a softening point of 60° C. and was found to be an excellent resist film free from creases and folds.

4. Formation of a Metal-Made Pattern Formation Mold

### Example 1c

The substrate on which the resist pattern of Example 1b had been formed was immersed in Microfab Au 100 (plating solution, product of Tanaka Kikinzoku Kogyo K.K.), and plating was performed at room temperature and a current density of 1 to 10 A/100 cm², to thereby form an Au plating layer (second layer). The thus-formed composite was immersed in an aqueous solution having a Cr(VI) oxide concentration of 250 g/L and a sulfuric acid concentration of 15 mL/L, to thereby remove copper from the substrate through etching. Subsequently, the thus-removed composite was immersed in an N-methylpyrrolidone solution at 120° C. for two hours for removing the resist pattern, to thereby produce a metal (Au)-made pattern formation mold.

### Comparative Example 2c

The procedure of Example 1c was repeated, except that a substrate on which the resist pattern of Comparative Example 2b was used instead of that of Example 1b, to thereby produce a metal (Au)-made pattern formation mold.

### Test Example 4

Each of the metal-made pattern formation molds produced in Example 1c and Comparative Example 2c was observed under a microscope, to thereby evaluate formation status. Specifically, the case in which the resist pattern was uniformly plated and a pattern was formed with high precision through transfer of the original resist pattern was assigned a rating “O.” Similarly, the case in which the resist pattern was not uniformly plated and/or failure in formation of a pattern formed through transfer of the original resist pattern was observed was assigned a rating “X.” The results are shown in Table 3.

5. Formation of a Resin-Made Pattern Formation Mold

### Example 1d

Onto the substrate on which the resist pattern of Example 1b had been formed, a mixture of unpolymerized PDMS (Sylgard 184, product of Dow Corning) and an initiator (monomer:initiator=10:1) was poured. The liquid was heated at 100° C. for two hours for polymerization. The substrate was cooled to room temperature, and the cured PDMS was physically peeled from the substrate, to thereby produce a resin (PDMS)-made pattern formation mold.

### Comparative Example 2d

The procedure of Example 1d was repeated, except that a substrate on which the resist pattern of Comparative Example 2b had been formed was used instead of that of Example 1b, to thereby produce a resin-made pattern formation mold.

### Test Example 5

Each of the resin-made pattern formation molds produced in Example 1d and Comparative Example 2d was observed under a microscope, to thereby evaluate formation status. Specifically, the case in which broken fragments of the original resist pattern did not adhere to the produced PDMS pattern and a pattern was formed with high precision through transfer of the original resist pattern was assigned a rating “O.” Similarly, the case in which the original resist pattern was broken and/or failure in formation of a pattern formed through transfer of the original resist pattern was observed was assigned a rating “X.” The results are shown in Table 3.

TABLE 3

| | | | Test Example | Test Example |
|---|---|---|---|---|
| | | Dose | 4 (metal | 5 (resin |
| | Light source | J/cm² | pattern) | pattern) |
| Examples 1c | High- | 1 | ◯ | ◯ |
| and 1d | pressure | | | |
| | mercury lamp | | | |
| | KrF | 10 | ◯ | ◯ |
| | Synchrotron | 100 | ◯ | ◯ |
| | radiation | | | |
| Comparative | High- | 1 | Resist pattern not formed | |
| Examples 2c | pressure | 100 | Resist pattern not formed | |
| and 2d | mercury lamp | | | |
| | KrF | 10 | Resist pattern not formed | |
| | Synchrotron | 100 | Resist pattern not formed | |
| | radiation | 10000 | ◯ | X |

As is clear from Table 3, excellent pattern formation molds made of metal and resin can be produced in Examples 1c and 1d. In other Examples, excellent resist patterns were produced. Thus, similar to the cases of Examples 1c and 1d, excellent pattern formation molds made of metal and resin could be formed. In contrast, as mentioned above, resist patterns were not formed in most cases of Comparative Examples 2c and 2d. Thus, a metal-made pattern formation mold and a resin-made pattern formation mold could not be formed. A resist pattern was formed under severe exposure conditions which are not practically employed (i.e., synchrotron radiation of 10,000 J/cm²). However, the resist pattern was found to have poor mechanical strength, and a resin-made pattern formation mold could not be produced smoothly.

### INDUSTRIAL APPLICABILITY

As described hereinabove, according to the present invention, there can be produced a pattern formation mold formed of metal, resin, etc. from a high-aspect resist pattern having high pattern precision, the high-aspect pattern being produced through a method in which a resist composition can be applied to a substrate in a simple manner so as to accurately control film thickness (e.g., spin coating); the target level of pattern precision and the light source for exposure can be selected from wide ranges; and high productivity is attained by virtue of requirement of a short exposure time.

1. A method for producing a pattern formation mold, characterized in that the method comprises: a first step of applying to a substrate a radiation-sensitive negative-type resist composition containing an epoxy resin represented by formula (1): 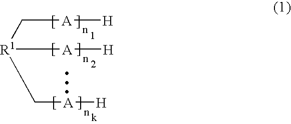
(wherein R¹ represents a moiety derived from an organic compound having k active hydrogen atoms (k represents an integer of 1 to 100); each of n₁, n₂, through nₖ represents 0 or an integer of 1 to 100; the sum of n₁, n₂, through nₖ falls within a range of 1 to 100; and each of “A”s, which may be identical to or different from each other, represents an oxycyclohexane skeleton represented by formula (2): 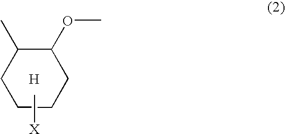
(wherein X represents any of groups represented by formulas (3) to (5): 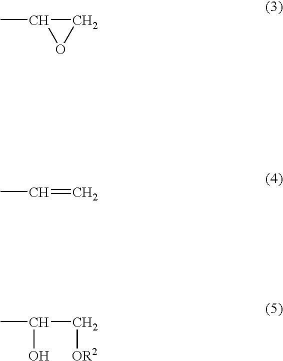
(wherein R² represents a hydrogen atom, an alkyl group, or an acyl group), and at least two groups represented by formula (3) are contained in one molecule of the epoxy resin)), along with a radiation-sensitive cationic polymerization initiator, and a solvent for dissolving the epoxy resin therein; a second step of drying the substrate coated with the radiation-sensitive negative-type resist composition, to thereby form a resist film; a third step of selectively exposing the formed resist film to an active energy beam according to a desired pattern; a fourth step of heating the exposed resist film so as to enhance a contrast of a pattern to be formed; a fifth step of developing the heated resist film, to thereby remove the unexposed area of the resist film through dissolution, thereby forming a patterned layer; and a sixth step of applying to the patterned layer a material other than that of the patterned layer such that spaces present in the patterned layer are filled, at least to some height, with the material, to thereby form a second layer, and removing the second layer, to thereby yield a pattern formation mold.

2. A method for producing a pattern formation mold according to claim 1, wherein the second layer is formed through metal plating.

3. A method for producing a pattern formation mold according to claim 1, wherein the second layer is formed by casting a photo-curable or heat-curable resin and curing the resin by light or heat.

4. A method for producing a pattern formation mold according to claim 1, wherein the resist film formed by drying the radiation-sensitive negative-type resist composition has a softening point falling within a range of 30 to 120° C.

5. A method for producing a pattern formation mold according to claim 1, wherein the epoxy resin has a softening point of 30° C. or higher.

6. A method for producing a pattern formation mold according to claim 1, wherein the radiation-sensitive cationic polymerization initiator comprises one or more sulfonium salts.

7. A method for producing a pattern formation mold according to claim 1, wherein the radiation-sensitive cationic polymerization initiator has one or more anion moieties, at least one species of the anion moieties being SbF₆⁻.

8. A method for producing a pattern formation mold according to claim 1, wherein the radiation-sensitive cationic polymerization initiator has one or more anion moieties, at least one species of the anion moieties being a borate represented by formula (6): 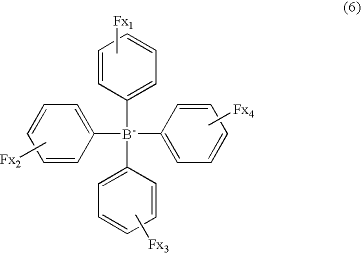
(wherein each of x₁ to x₄ represents an integer of 0 to 5, and the sum x₁+x₂+x₃+x₄ is 1 or more).

9. A method for producing a pattern formation mold according to claim 1, wherein the active energy beam is an X-ray having a wavelength of 0.1 to 5 nm.

10. A method for producing a pattern formation mold according to claim 1, wherein the resist film has a thickness of at least 50 μm.
